(19) United States
(12) Patent Application Publication
(10) Pub. No.: US 2026/0065984 A1
(43) Pub. Date: Mar. 5, 2026

(54) WEIGHT SCALING FOR NEURAL NETWORK

(71) Applicant: Silicon Storage Technology, Inc., San Jose, CA (US)

(72) Inventor: Hieu Van Tran, San Jose, CA (US)

(21) Appl. No.: 18/943,881

(22) Filed: Nov. 11, 2024

Related U.S. Application Data
(60) Provisional application No. 63/689,408, filed on Aug. 30, 2024.

(51) Int. Cl. G11C 11/54; G06N 3/065; G11C 16/10; G11C 16/26

(52) U.S. Cl. CPC G11C 11/54; G06N 3/065; G11C 16/10; G11C 16/26

(57) ABSTRACT

In one example, a system comprises an array of non-volatile memory cells arranged in rows and columns; a control gate bias generator to generate a bias voltage to apply to a control gate line coupled to a row of non-volatile memory cells in the array; and an algorithm controller to configure the control gate bias generator based on the layer of a neural network to be stored in the array.

### PRIORITY CLAIM

This application claims priority to U.S. Provisional Patent Application No. 63/689,408, filed on Aug. 30, 2024, and titled, “Weight Scaling for Neural Network,” which is incorporated by reference herein.

### FIELD OF THE INVENTION

Numerous examples are disclosed of systems and method for scaling the weights stored in an array of non-volatile memory cells for a layer of a neural network.

### BACKGROUND OF THE INVENTION

Artificial neural networks mimic biological neural networks (the central nervous systems of animals, in particular the brain) and are used to estimate or approximate functions that can depend on a large number of inputs and are generally unknown. Artificial neural networks generally include layers of interconnected “neurons” which exchange messages between each other.

FIG. 1 illustrates an artificial neural network 100, where the circles represent the inputs or layers of neurons. The connections (called synapses) are represented by arrows and have numeric weights that can be tuned based on experience. This makes neural networks adaptive to inputs and capable of learning. Typically, neural networks include a layer of multiple inputs. There are typically one or more intermediate layers of neurons, and an output layer of neurons that provide the output of the neural network. The neurons at each level individually or collectively make a decision based on the received data from the synapses.

One of the major challenges in the development of artificial neural networks for high-performance information processing is a lack of adequate hardware technology. Indeed, practical neural networks rely on a very large number of synapses, enabling high connectivity between neurons, i.e., a very high computational parallelism. In principle, such complexity can be achieved with digital supercomputers or graphics processing unit clusters. However, in addition to high cost, these approaches also suffer from mediocre energy efficiency as compared to biological networks, which consume much less energy primarily because they perform low-precision analog computation. CMOS analog circuits have been used for artificial neural networks, but most CMOS-implemented synapses have been too bulky given the high number of neurons and synapses.

Applicant previously disclosed an artificial (analog) neural network that utilizes one or more non-volatile memory arrays as the synapses in U.S. Patent Application Publication 2017/0337466A1, which is incorporated by reference. The non-volatile memory arrays operate as an analog neural memory and comprise non-volatile memory cells arranged in rows and columns. The neural network includes a first plurality of synapses configured to receive a first plurality of inputs and to generate therefrom a first plurality of outputs, and a first plurality of neurons configured to receive the first plurality of outputs. The first plurality of synapses includes a plurality of memory cells, wherein each of the memory cells includes spaced apart source and drain regions formed in a semiconductor substrate with a channel region extending there between, a floating gate disposed over and insulated from a first portion of the channel region and a non-floating gate disposed over and insulated from a second portion of the channel region. Each of the plurality of memory cells store a weight value corresponding to a number of electrons on the floating gate. The plurality of memory cells multiply the first plurality of inputs by the stored weight values to generate the first plurality of outputs.

### Non-Volatile Memory Cells

Non-volatile memories are well known. For example, U.S. Pat. No. 5,029,130 (“the '130 patent”), which is incorporated herein by reference, discloses an array of split gate non-volatile memory cells, which are a type of flash memory cells. Such a memory cell 210 is shown in FIG. 2. Each memory cell 210 includes source region 14 and drain region 16 formed in semiconductor substrate 12, with channel region 18 there between. Floating gate 20 is formed over and insulated from (and controls the conductivity of) a first portion of the channel region 18, and over a portion of the source region 14. Word line terminal 22 (which is typically coupled to a word line) has a first portion that is disposed over and insulated from (and controls the conductivity of) a second portion of the channel region 18, and a second portion that extends up and over the floating gate 20. The floating gate 20 and word line terminal 22 are insulated from the substrate 12 by a gate oxide. Bitline 24 is coupled to drain region 16.

Memory cell 210 is erased (where electrons are removed from the floating gate) by placing a high positive voltage on the word line terminal 22, which causes electrons on the floating gate 20 to tunnel through the intermediate insulation from the floating gate 20 to the word line terminal 22 via Fowler-Nordheim (FN) tunneling.

Memory cell 210 is programmed by source side injection (SSI) with hot electrons (where electrons are placed on the floating gate) by placing a positive voltage on the word line terminal 22, and a positive voltage on the source region 14. Electron current will flow from the drain region 16 towards the source region 14. The electrons will accelerate and become heated when they reach the gap between the word line terminal 22 and the floating gate 20. Some of the heated electrons will be injected through the gate oxide onto the floating gate 20 due to the attractive electrostatic force from the floating gate 20.

Memory cell 210 is read by placing positive read voltages on the drain region 16 and word line terminal 22 (which turns on the portion of the channel region 18 under the word line terminal). If the floating gate 20 is positively charged (i.e., erased of electrons), then the portion of the channel region 18 under the floating gate 20 is turned on as well, and current will flow across the channel region 18, which is sensed as the erased or “1” state. If the floating gate 20 is negatively charged (i.e., programmed with electrons), then the portion of the channel region under the floating gate 20 is mostly or entirely turned off, and current will not flow (or there will be little flow) across the channel region 18, which is sensed as the programmed or “0” state.

Table No. 1 depicts typical voltage and current ranges that can be applied to the terminals of memory cell 210 for performing read, erase, and program operations:

TABLE NO 1
Operation of Flash Memory Cell 210 of FIG. 2

| | | |
|---|---|---|
| WL | BL | SL |

| | | | | | | |
|---|---|---|---|---|---|---|
| Read | 2-3 | V | 0.6-2 | V | 0 | V |
| Erase | ~11-13 | V | 0 | V | 0 | V |
| Program | 1-2 | V | 10.5-3 | μA | 9-10 | V |

Other split gate memory cell configurations, which are other types of flash memory cells, are known. For example, FIG. 3 depicts a four-gate memory cell 310 comprising source region 14, drain region 16, floating gate 20 over a first portion of channel region 18, a select gate 22 (typically coupled to a word line, WL) over a second portion of the channel region 18, a control gate 28 over the floating gate 20, and an erase gate 30 over the source region 14. This configuration is described in U.S. Pat. No. 6,747,310, which is incorporated herein by reference for all purposes. Here, all gates are non-floating gates except floating gate 20, meaning that they are electrically connected or connectable to a voltage source. Programming is performed by heated electrons from the channel region 18 injecting themselves onto the floating gate 20. Erasing is performed by electrons tunneling from the floating gate 20 to the erase gate 30.

Table No. 2 depicts typical voltage and current ranges that can be applied to the terminals of memory cell 310 for performing read, erase, and program operations:

TABLE NO 2
Operation of Flash Memory Cell 310 of FIG. 3

| | WL/SG | | BL | | CG | | EG | | SL | |
|---|---|---|---|---|---|---|---|---|---|---|
| Read | 1.0-2 | V | 0.6-2 | V | 0-2.6 | V | 0-2.6 | V | 0 | V |
| Erase | −0.5 V/0 V | | 0 | V | 0 V/−8 V | | 8-12 | V | 0 | V |
| Program | 1 | V | 0.1-1 | μA | 8-11 | V | 4.5-9 | V | 4.5-5 | V |

FIG. 4 depicts a three-gate memory cell 410, which is another type of flash memory cell. Memory cell 410 is identical to the memory cell 310 of FIG. 3 except that memory cell 410 does not have a separate control gate. The erase operation (whereby erasing occurs through use of the erase gate) and read operation are similar to that of the FIG. 3 except there is no control gate bias applied. The programming operation also is done without the control gate bias, and as a result, a higher voltage is applied on the source line during a program operation to compensate for a lack of control gate bias.

Table No. 3 depicts typical voltage and current ranges that can be applied to the terminals of memory cell 410 for performing read, erase, and program operations:

TABLE NO 3
Operation of Flash Memory Cell 410 of FIG. 4

| | | | |
|---|---|---|---|
| WL/SG | BL | EG | SL |

| | | | | | | | | |
|---|---|---|---|---|---|---|---|---|
| Read | 0.7-2.2 | V | 0.6-2 | V | 0-2.6 | V | 0 | V |

| | | | | | | | |
|---|---|---|---|---|---|---|---|
| Erase | −0.5 V/0 V | 0 | V | 11.5 | V | 0 | V |

| | | | | | | | | |
|---|---|---|---|---|---|---|---|---|
| Program | 1 | V | 0.2-3 | μA | 4.5 | V | 7-9 | V |

FIG. 5 depicts stacked gate memory cell 510, which is another type of flash memory cell. Memory cell 510 is similar to memory cell 210 of FIG. 2, except that floating gate 20 extends over the entire channel region 18, and control gate 22 (which here will be coupled to a word line) extends over floating gate 20, separated by an insulating layer (not shown). The erase is done by FN tunneling of electrons from FG to substrate, programming is by channel hot electron (CHE) injection at region between the channel 18 and the drain region 16, by the electrons flowing from the source region 14 towards to drain region 16 and read operation which is similar to that for memory cell 210 with a higher control gate voltage.

Table No. 4 depicts typical voltage ranges that can be applied to the terminals of memory cell 510 and substrate 12 for performing read, erase, and program operations:

TABLE NO 4
Operation of Flash Memory Cell 510 of FIG. 5

| | CG | | BL | | SL | | Substrate | |
|---|---|---|---|---|---|---|---|---|
| Read | 2-5 | V | 0.6-2 | V | 0 | V | 0 | V |
| Erase | −8 to −10 V/0 V | | FLT | | FLT | | 8-10 V/15-20 V | |
| Program | 8-12 | V | 3-5 | V | 0 | V | 0 | V |

The methods and means described herein may apply to other non-volatile memory technologies such as FINFET split gate flash or stack gate flash memory, NAND flash, SONOS (silicon-oxide-nitride-oxide-silicon, charge trap in nitride), MONOS (metal-oxide-nitride-oxide-silicon, metal charge trap in nitride), ReRAM (resistive ram), PCM (phase change memory), MRAM (magnetic ram), FeRAM (ferroelectric ram), CT (charge trap) memory, CN (carbon-tube) memory, OTP (bi-level or multi-level one time programmable), and CeRAM (correlated electron ram), without limitation.

In order to utilize the memory arrays comprising one of the types of non-volatile memory cells described above in an artificial neural network, two modifications are made. First, the lines are configured so that each memory cell can be individually programmed, erased, and read without adversely affecting the memory state of other memory cells in the array, as further explained below. Second, continuous (analog) programming of the memory cells is provided.

Specifically, the memory state (i.e., charge on the floating gate) of each memory cell in the array can be continuously changed from a fully erased state to a fully programmed state, and vice-versa, independently and with minimal disturbance of other memory cells. This means the cell storage is effectively analog or at the very least can store one of many discrete values (such as 16 or 64 different values), which allows for very precise and individual tuning of all the memory cells in the memory array, and which makes the memory array ideal for storing and making fine tuning adjustments to the synapsis weights of the neural network.

### Neural Networks Employing Non-Volatile Memory Cell Arrays

FIG. 6 conceptually illustrates a non-limiting example of a neural network utilizing a non-volatile memory array of the present examples. This example uses the non-volatile memory array neural network for a facial recognition application, but any other appropriate application could be implemented using a non-volatile memory array based neural network.

SO is the input layer, which for this example is a 32×32 pixel RGB image with 5 bit precision (i.e. three 32×32 pixel arrays, one for each color R, G and B, each pixel being 5 bit precision). The synapses CB1 going from input layer SO to layer C1 apply different sets of weights in some instances and shared weights in other instances and scan the input image with 3×3 pixel overlapping filters (kernel), shifting the filter by 1 pixel (or more than 1 pixel as dictated by the model). Specifically, values for 9 pixels in a 3×3 portion of the image (i.e., referred to as a filter or kernel) are provided to the synapses CB1, where these 9 input values are multiplied by the appropriate weights and, after summing the outputs of that multiplication, a single output value is determined and provided by a first synapse of CB1 for generating a pixel of one of the feature maps of layer C1. The 3×3 filter is then shifted one pixel to the right within input layer SO (i.e., adding the column of three pixels on the right, and dropping the column of three pixels on the left), whereby the 9 pixel values in this newly positioned filter are provided to the synapses CB1, where they are multiplied by the same weights and a second single output value is determined by the associated synapse. This process is continued until the 3×3 filter scans across the entire 32×32 pixel image of input layer SO, for all three colors and for all bits (precision values). The process is then repeated using different sets of weights to generate a different feature map of layer C1, until all the features maps of layer C1 have been calculated.

In layer C1, in the present example, there are 16 feature maps, with 30×30 pixels each. Each pixel is a new feature pixel extracted from multiplying the inputs and kernel, and therefore each feature map is a two dimensional array, and thus in this example layer C1 constitutes 16 layers of two dimensional arrays (keeping in mind that the layers and arrays referenced herein are logical relationships and may not be physical relationships—i.e., the arrays might not be oriented in physical two dimensional arrays). Each of the 16 feature maps in layer C1 is generated by one of sixteen different sets of synapse weights applied to the filter scans. The C1 feature maps could all be directed to different aspects of the same image feature, such as boundary identification. For example, the first map (generated using a first weight set, shared for all scans used to generate this first map) could identify circular edges, the second map (generated using a second weight set different from the first weight set) could identify rectangular edges, or the aspect ratio of certain features, and so on.

An activation function P1 (pooling) is applied before going from layer C1 to layer S1, which pools values from consecutive, non-overlapping 2×2 regions in each feature map. The purpose of the pooling function P1 is to average out the nearby location (or a max function can also be used), to reduce the dependence of the edge location for example and to reduce the data size before going to the next stage. At layer S1, there are 16 15×15 feature maps (i.e., sixteen different arrays of 15×15 pixels each). The synapses CB2 going from layer S1 to layer C2 scan maps in layer S1 with 4×4 filters, with a filter shift of 1 pixel. At layer C2, there are 22 12×12 feature maps. An activation function P2 (pooling) is applied before going from layer C2 to layer S2, which pools values from consecutive non-overlapping 2×2 regions in each feature map. At layer S2, there are 22 6×6 feature maps. An activation function (pooling) is applied at the synapses CB3 going from layer S2 to layer C3, where every neuron in layer C3 connects to every map in layer S2 via a respective synapse of CB3. At layer C3, there are 64 neurons. The synapses CB4 going from layer C3 to the output layer S3 fully connects C3 to S3, i.e. every neuron in layer C3 is connected to every neuron in layer S3. The output at S3 includes 10 neurons, where the highest output neuron determines the class. This output could, for example, be indicative of an identification or classification of the contents of the original image.

Each layer of synapses is implemented using an array, or a portion of an array, of non-volatile memory cells.

FIG. 7 is a block diagram of an array that can be used for that purpose. Vector-by-matrix multiplication (VMM) array 32 includes non-volatile memory cells and is utilized as the synapses (such as CB1, CB2, CB3, and CB4 in FIG. 6) between one layer and the next layer. Specifically, VMM array 32 includes an array of non-volatile memory cells 33, erase gate and word line gate decoder 34, control gate decoder 35, bit line decoder 36 and source line decoder 37, which decode the respective inputs for the non-volatile memory cell array 33. Input to VMM array 32 can be from the erase gate and wordline gate decoder 34 or from the control gate decoder 35. Source line decoder 37 in this example also decodes the output of the non-volatile memory cell array 33. Alternatively, bit line decoder 36 can decode the output of the non-volatile memory cell array 33.

Non-volatile memory cell array 33 serves two purposes. First, it stores the weights that will be used by the VMM array 32. Second, the non-volatile memory cell array 33 effectively multiplies the inputs by the weights stored in the non-volatile memory cell array 33 and adds them up per output line (source line or bit line) to produce the output, which will be the input to the next layer or input to the final layer. By performing the multiplication and addition function, the non-volatile memory cell array 33 negates the use of separate multiplication and addition logic circuits and is also power efficient due to its in-situ memory computation.

The output of non-volatile memory cell array 33 is supplied to a differential summer (such as a summing op-amp or a summing current mirror) 38, which sums up the outputs of the non-volatile memory cell array 33 to create a single value for that convolution. The differential summer 38 is arranged to perform summation of positive weight and negative weight.

The summed-up output values of differential summer 38 are then supplied to an activation function block 39, which rectifies the output. The activation function block 39 may provide sigmoid, tanh, or RcLU functions. The rectified output values of activation function block 39 become an element of a feature map as the next layer (e.g. C1 in FIG. 6), and are then applied to the next synapse to produce the next feature map layer or final layer. Therefore, in this example, non-volatile memory cell array 33 constitutes a plurality of synapses (which receive their inputs from the prior layer of neurons or from an input layer such as an image database), and summing op-amp 38 and activation function block 39 constitute a plurality of neurons.

The input to VMM array 32 in FIG. 7 (WLx, EGx, CGx, and optionally BLx and SLx) can be analog level, binary level, or digital bits (in which case a DAC is provided to convert digital bits to appropriate input analog level) and the output can be analog level, binary level, or digital bits (in which case an output ADC is provided to convert output analog level into digital bits).

FIG. 8 is a block diagram depicting the usage of numerous layers of VMM arrays 32, here labeled as VMM arrays 32a, 32b, 32c, 32d, and 32c. As shown in FIG. 8, the input, denoted Inputx, is converted from digital to analog by a digital-to-analog converter 31 and provided to input VMM array 32a. The converted analog inputs could be voltage or current. The input D/A conversion for the first layer could be done by using a function or a LUT (look up table) that maps the inputs Inputx to appropriate analog levels for the matrix multiplier of input VMM array 32a. The input conversion could also be done by an analog to analog (A/A) converter to convert an external analog input to a mapped analog input to the input VMM array 32a.

The output generated by input VMM array 32a is provided as an input to the next VMM array (hidden level 1) 32b, which in turn generates an output that is provided as an input to the next VMM array (hidden level 2) 32c, and so on. The various layers of VMM array 32 function as different layers of synapses and neurons of a convolutional neural network (CNN). Each VMM array 32a, 32b, 32c, 32d, and 32e can be a stand-alone, physical non-volatile memory array, or multiple VMM arrays could utilize different portions of the same physical non-volatile memory array, or multiple VMM arrays could utilize overlapping portions of the same physical non-volatile memory array. The example shown in FIG. 8 contains five layers (32a,32b,32c,32d,32e): one input layer (32a), two hidden layers (32b,32c), and two fully connected layers (32d,32e). One of ordinary skill in the art will appreciate that this is merely an example and that a system instead could comprise more than two hidden layers and more than two fully connected layers.

Each layer in a neural network can represent different data patterns or different features resulting in different output ranges for the array outputs for the vector-by-matrix multiplication array. As a result, each layer in a neural network can have a different distribution of weights that are stored in the VMM array.

This can be seen, for example, in FIGS. 9A, 9B, and 9C, which depict the distribution of weights in Layers 0, 1, and 21 of a Yolo5m neural network. Although the value 0.00 is the most common weight in each layer, the range of weight distributions is significantly different among the three layers, with weights in Layer 0 ranging between −10 and +10 and weights in Layer 21 ranging between −0.2 and +0.2.

FIG. 10 depicts a prior art VMM system 1000 performing a read operation. VMM array 1001 comprises an array of non-volatile memory cells arranged into I rows and J columns. During a read operation, activation inputs Xᵢ are applied to the I rows, where i ranges from 1 to I and where each row can receive a different value. Each cell has been programmed to store a weight, Wᵢⱼ, where j ranges from 1 to J. Each cell then outputs a current representing a multiplication of its received activation input, Xᵢ, and its stored weight, Wᵢⱼ. Current is output on a column-by-column basis, with each column outputting the sum of the products of Xᵢ and Wᵢⱼ for each cell in that column, or Yⱼ=Σ(xᵢ*Wᵢⱼ), where the summation ranges from i=1 to i=I. The current outputs are then converted into voltages by current-to-voltage block 1002 and the converted into digital form by analog-to-digital converter block 1003. The digital outputs then can be optionally scaled by scaling block 1004, optionally normalized by normalization block 1005, and operated on by an activation function by activation block 1006.

Due to the variation in weight ranges among different layers in a single neural network as well as among different neural networks, a wide range of values are provided to ITV 1002 and ADC 1003. ITV 1002 and ADC 1003 therefore are designed to accommodate a wide range of possible values, which is associated with trade-offs in resolution, area, and performance. Reducing the range of values received by ITV 1002 and ADC 1003 would increase resolution and performance and require less area.

What is needed is an improved system and methods for scaling the weights stored in a VMM in a way that takes into account the difference in distribution among different layers and neural networks to reduce the range of the values that are provided to the ITV and ADC in the output stage.

### SUMMARY OF THE INVENTION

Numerous examples are disclosed of systems and method for scaling the weights stored in an array of non-volatile memory cells for a layer of a neural network.

In one example, a system comprises an array of non-volatile memory cells arranged in rows and columns; a control gate bias generator to generate a bias voltage to apply to a control gate line coupled to a row of non-volatile memory cells in the array; and an algorithm controller to configure the control gate bias generator to generate a control gate bias based on a layer of a neural network to be stored in the array.

In another example, a method comprises receiving a first set of weight values; and programming a second set of weight values into non-volatile memory cells, where the second set of weight values are equal to the first set of weight values scaled by a scaling factor S, and the scaling is achieved by storing each weight value in the first set of weight values in S non-volatile memory cells.

In another example, a method comprises receiving a first set of weight values; and programming a second set of weight values into non-volatile memory cells, where the second set of weight values are equal to the first set of weight values scaled by a scaling factor S, where S is based on a distribution of input values and the full scale range of the input values.

In another example, a method comprises receiving a first set of weight values; and programming a second set of weight values into non-volatile memory cells, where the second set of weight values are equal to the first set of weight values scaled by a scaling factor S, where S is based on a distribution of weights in the first set of weight values and the full scale range of the weight values in the first set of weight values.

In another example, a method comprises receiving a first set of weight values; and programming a second set of weight values into non-volatile memory cells, where the second set of weight values are equal to the first set of weight values scaled by a scaling factor S, where S is based on: (i) a distribution of input values and the full scale range of the input values; (ii) a distribution of weights in the first set of weight values and the full scale range of the weight values; and (iii) a distribution of neuron distribution values and the full scale range of neuron distribution values.

In another example, a method comprises reading a plurality of non-volatile memory cells in an array of non-volatile memory cells to produce a single weight value in a layer of a neural network.

In another example, a method comprises reading memory cells storing a scaled weight value.

### BRIEF DESCRIPTION OF THE DRAWINGS

FIG. 1 is a diagram that illustrates an artificial neural network.

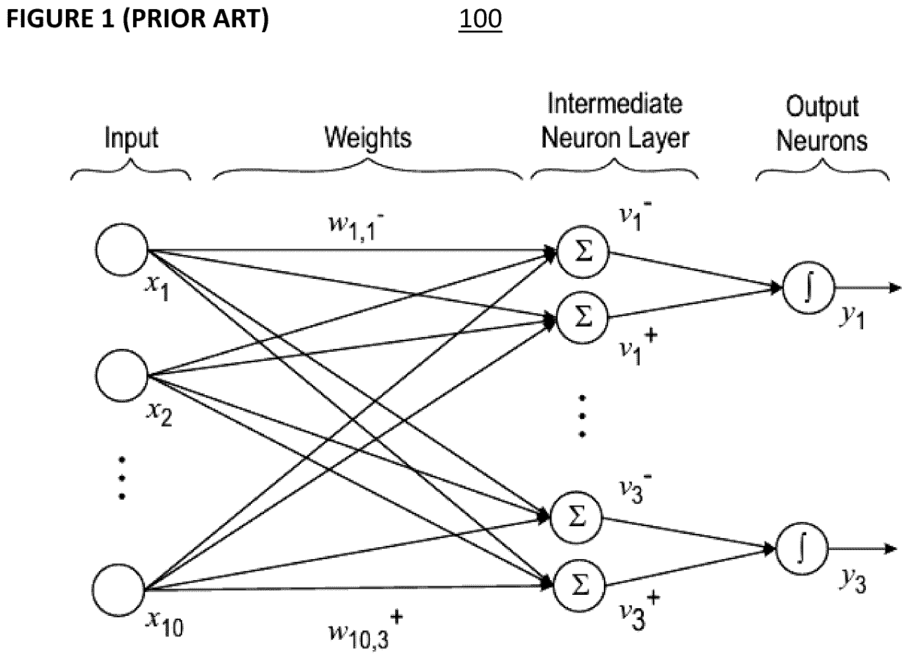

FIG. 2 depicts a prior art split gate flash memory cell.

FIG. 3 depicts another prior art split gate flash memory cell.

FIG. 4 depicts another prior art split gate flash memory cell.

FIG. 5 depicts another prior art split gate flash memory cell.

FIG. 6 is a diagram illustrating the different levels of an example prior art artificial neural network utilizing one or more non-volatile memory arrays.

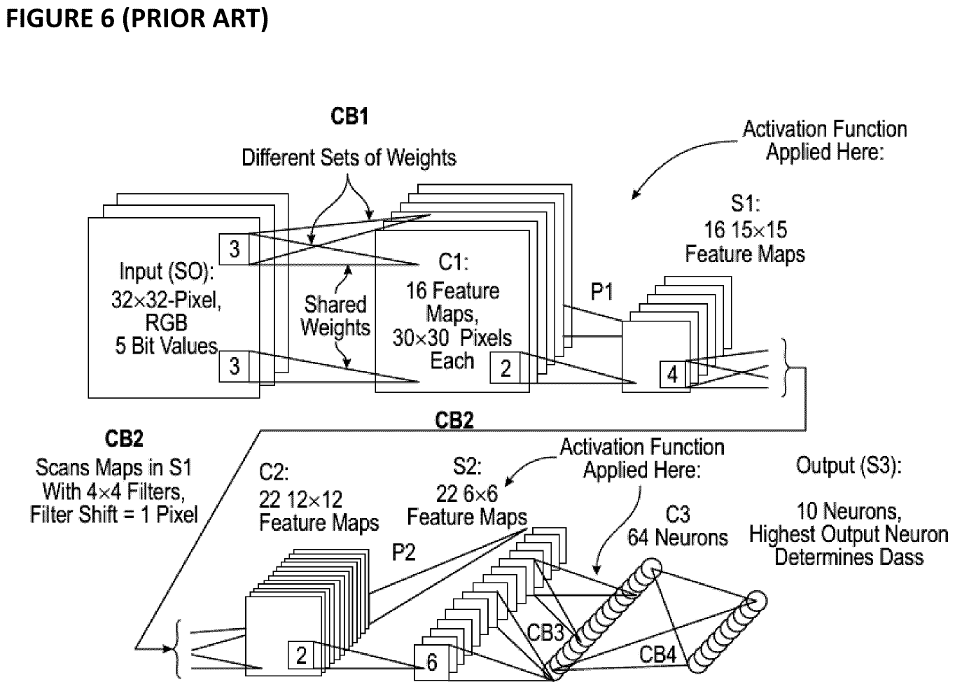

FIG. 7 is a block diagram illustrating a prior art VMM system.

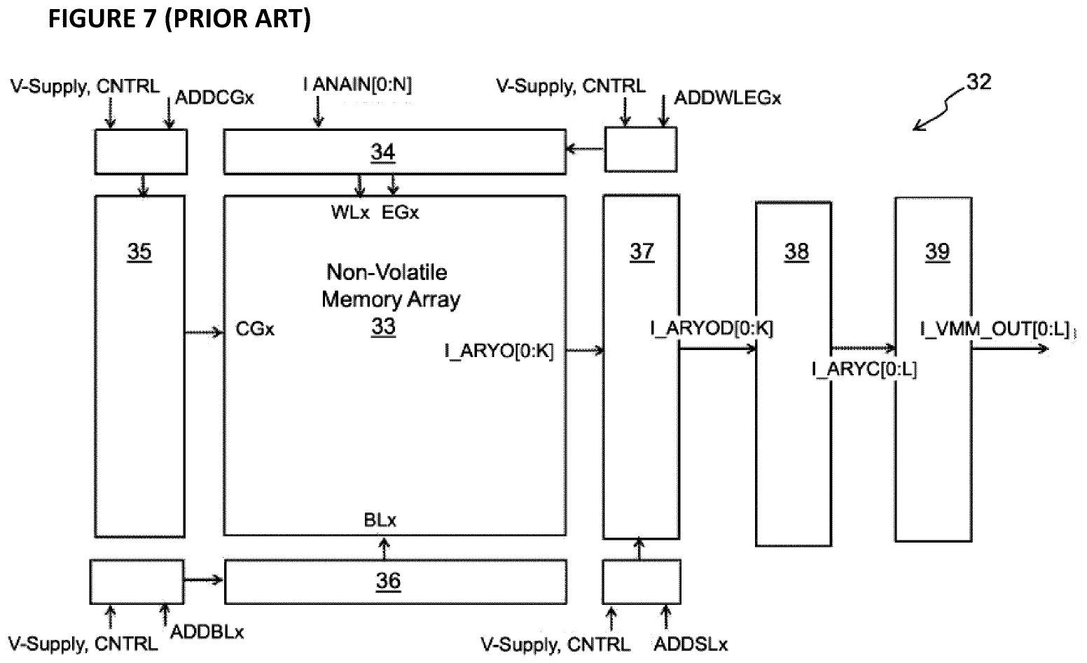

FIG. 8 is a block diagram illustrates an example prior art artificial neural network utilizing one or more VMM systems.

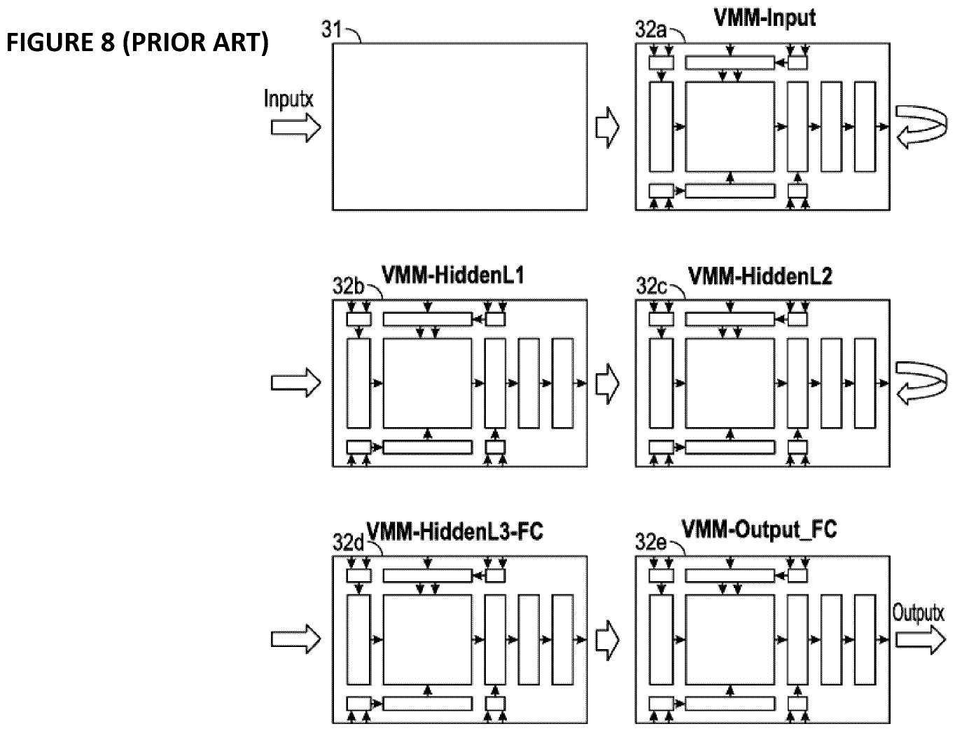

FIGS. 9A, 9B, and 9C depict weight distributions for different layers of a prior art Yolo5m neural network.

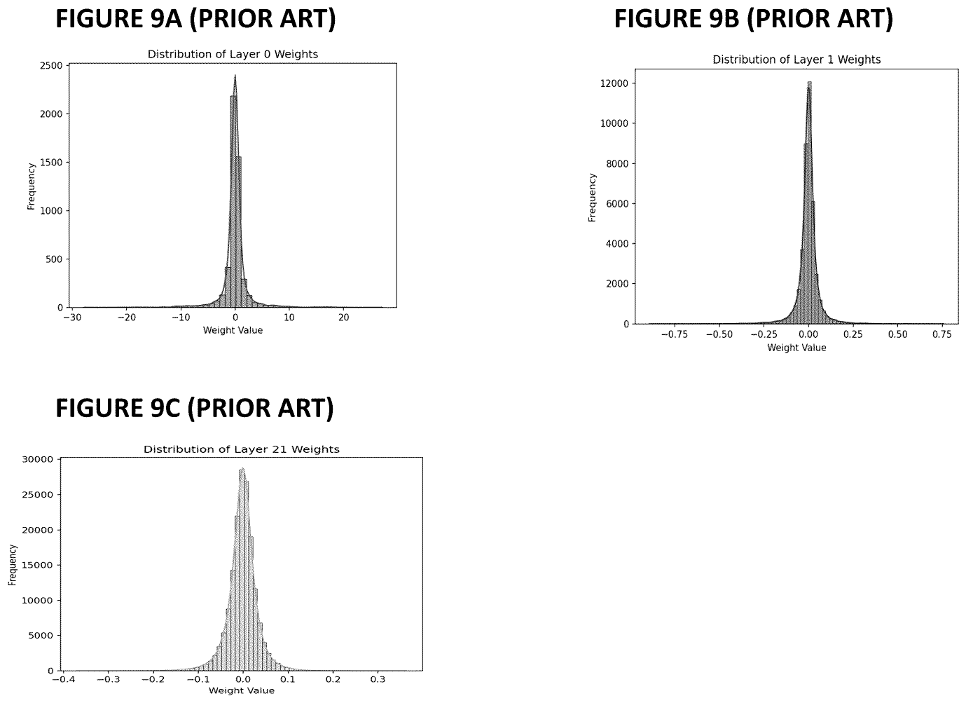

FIG. 10 depicts a prior art VMM system.

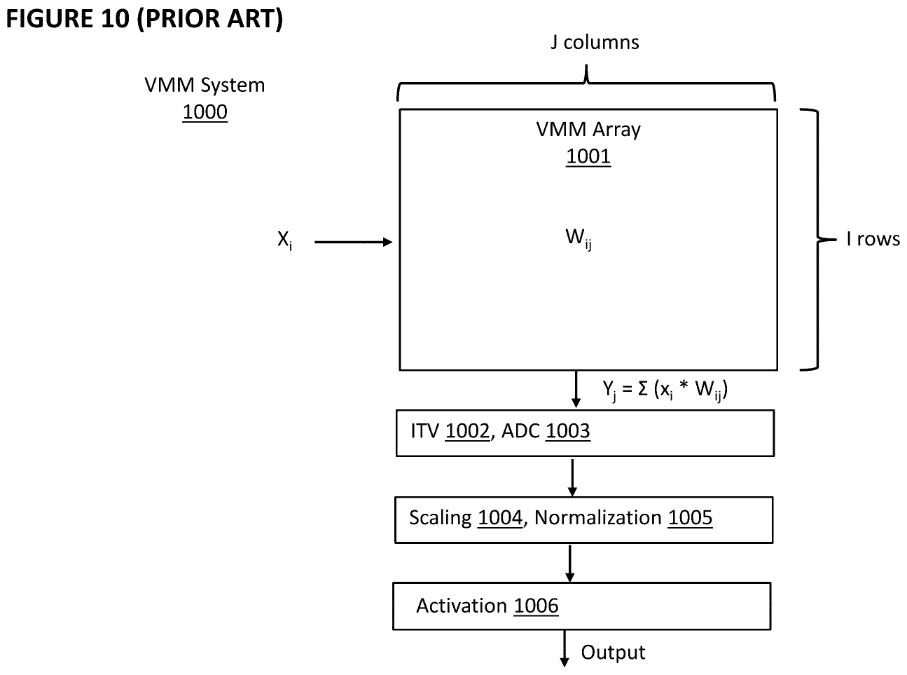

FIG. 11 depicts a VMM system.

FIG. 12A depicts a VMM system.

FIG. 12B depicts a VMM system.

FIG. 12C depicts a VMM system.

FIG. 13 depicts a weight distribution.

FIG. 14 depicts a weight distribution.

FIG. 15 depicts a DAC input distribution.

FIG. 16 depicts an output neuron distribution.

### DETAILED DESCRIPTION OF THE INVENTION

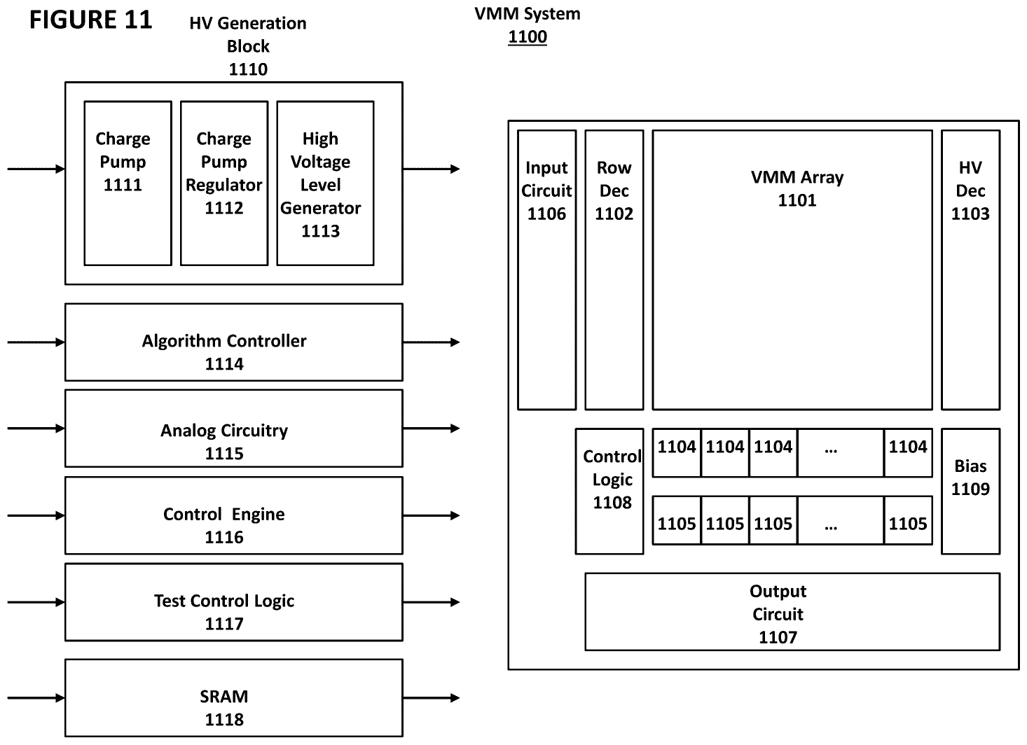

FIG. 11 depicts a block diagram of VMM system 1100. VMM system 1100 comprises VMM array 1101, row decoder 1102, high voltage decoder 1103, column decoders 1104, bit line drivers 1105 (such as bit line control circuitry for programming), input circuit 1106, output circuit 1107, control logic 1108, and bias generator 1109. VMM system 1100 further comprises high voltage generation block 1110, which comprises charge pump 1111, charge pump regulator 1112, and high voltage level generator 1113. VMM system 1100 further comprises algorithm controller 1114 (which can control operations for programming, erasing, weight tuning, and as discussed below, weight scaling), analog circuitry 1115, control engine 1116 (which can perform functions such as arithmetic functions, activation functions, and embedded microcontroller logic), test control logic 1117, and static random access memory (SRAM) block 1118 to store intermediate data such as for input circuits (e.g., activation data) or output circuits (neuron output data, partial sum output neuron data) or data-in for programming (such as data-in for a whole row or multiple rows).

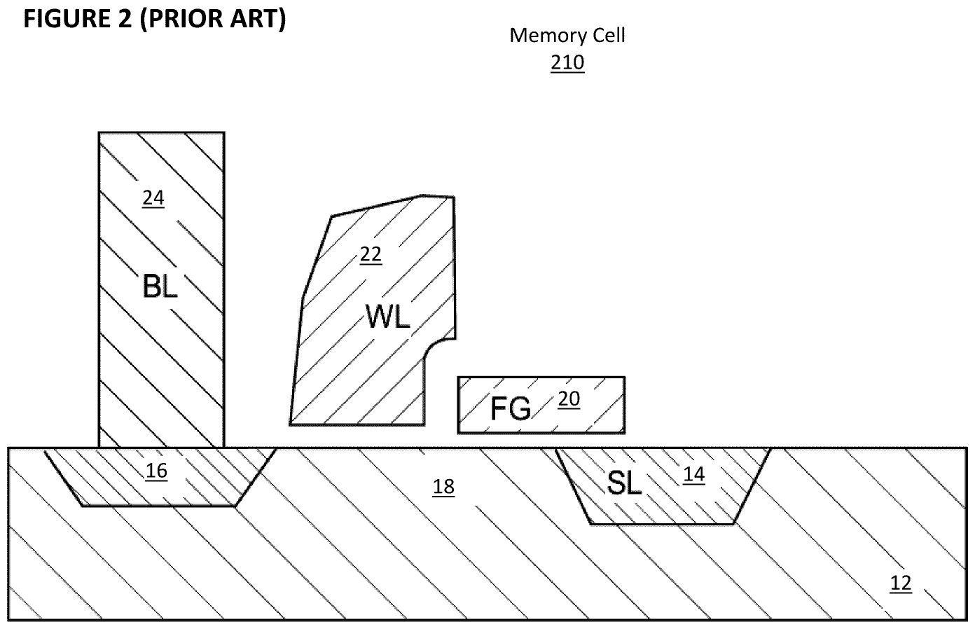

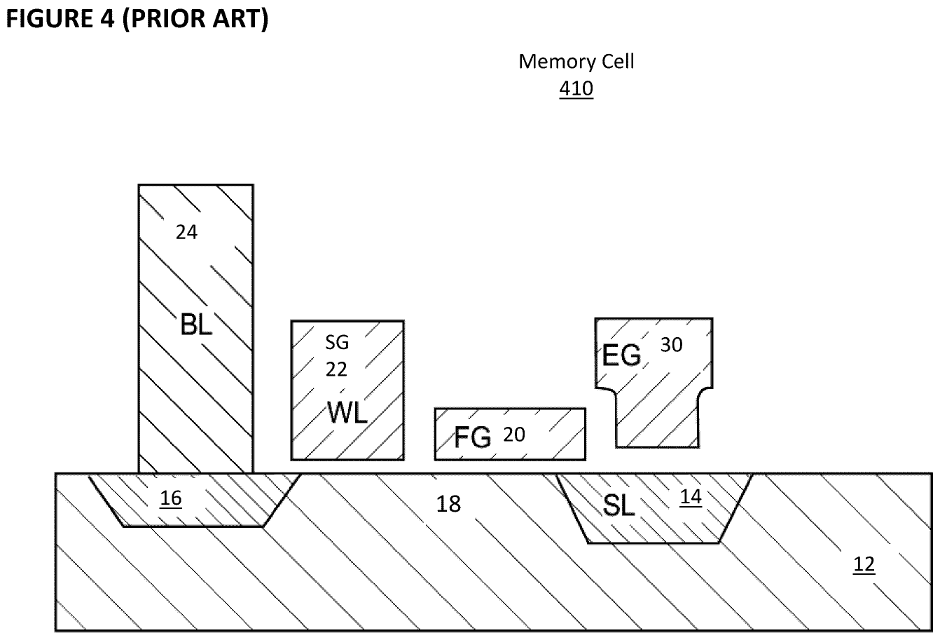

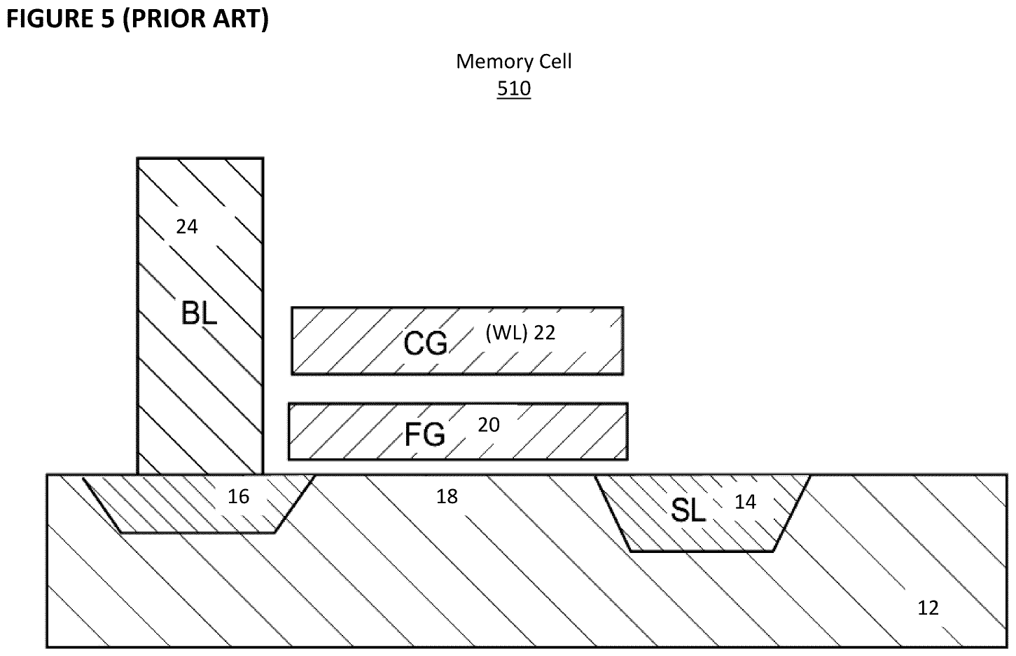

VMM array 1101 comprises an array of non-volatile memory cells arranges in rows and columns. In one example, the memory cells of VMM array 1101 comprise split-gate flash memory cells such as cells based on the design of memory cell 210, 310, or 410 in FIGS. 2, 3, and 4, respectively. In another example, the memory cells of VMM array 1101 comprise stacked-gate flash memory cells such as cells based on the design of memory cell 510 in FIG. 5.

Input circuit 1106 may include circuits such as a DAC (digital to analog converter), DPC (digital to pulses converter, digital to time modulated pulse converter), AAC (analog to analog converter, such as a current to voltage converter, logarithmic converter), PAC (pulse to analog level converter), or any other type of converters. Input circuit 1106 may implement one or more of normalization, linear or non-linear up/down scaling functions, or arithmetic functions. Input circuit 1106 may implement a temperature compensation function for input levels. Input circuit 1106 may implement an activation function such as ReLU or sigmoid. Input circuit 1106 may store digital activation data to be applied as, or combined with, an input signal during a program or read operation. The digital activation data can be stored in registers. Input circuit 1106 may comprise circuits to drive the array terminals, such as CG, WL, EG, and SL lines, which may include sample-and-hold circuits and buffers. A DAC can be used to convert digital activation data into an analog input voltage to be applied to the array. As discussed below, input circuit 1106 also performs weight scaling.

Output circuit 1107 may include circuits such as an ITV (current-to-voltage circuit), ADC (analog to digital converter, to convert neuron analog output to digital bits), AAC (analog to analog converter, such as a current to voltage converter, logarithmic converter), APC (analog to pulse(s) converter, analog to time modulated pulse converter), or any other type of converters. Output circuit 1107 may convert array outputs into activation data. Output circuit 1107 may implement an activation function such as rectified linear activation function (ReLU) or sigmoid. Output circuit 1107 may implement one or more of statistic normalization, regularization, up/down scaling/gain functions, statistical rounding, or arithmetic functions (e.g., add, subtract, divide, multiply, shift, log) for neuron outputs. Output circuit 1107 may implement a temperature compensation function for neuron outputs or array outputs (such as bitline output) so as to keep power consumption of the array approximately constant or to improve precision of the array (neuron) outputs such as by keeping the IV slope approximately the same over temperature. Output circuit 1107 may comprise registers for storing output data.

In the examples that follow, input circuit 1106 applies a bias voltage to a control gate line during programming of cells in the row connected to that control gate line, which alters the weight that is programmed into the cells, thereby implementing a scaling algorithm for the weights stored in VMM array 1101.

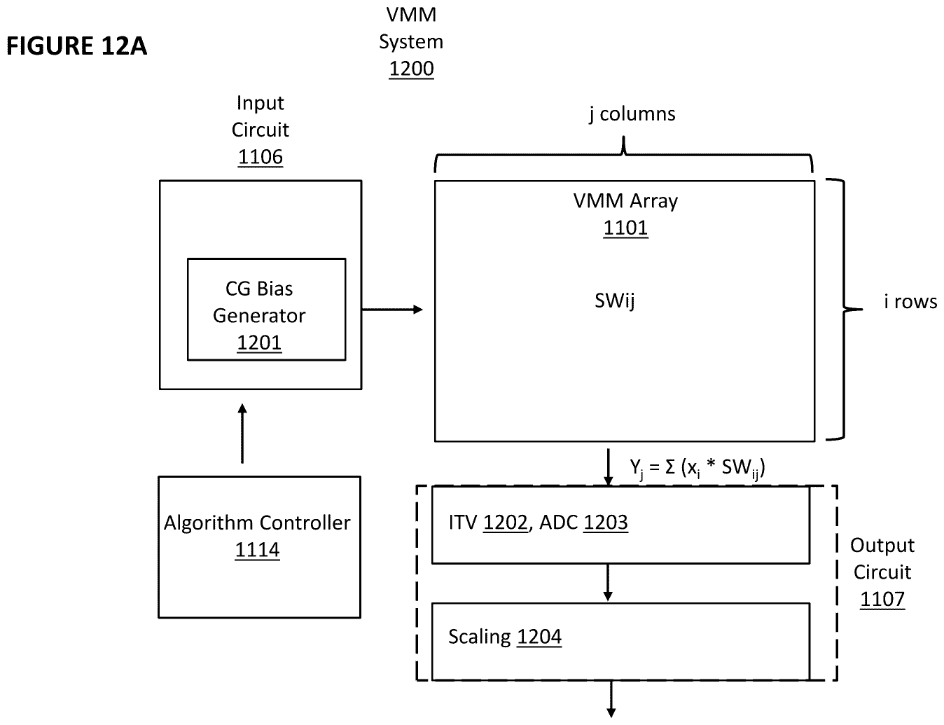

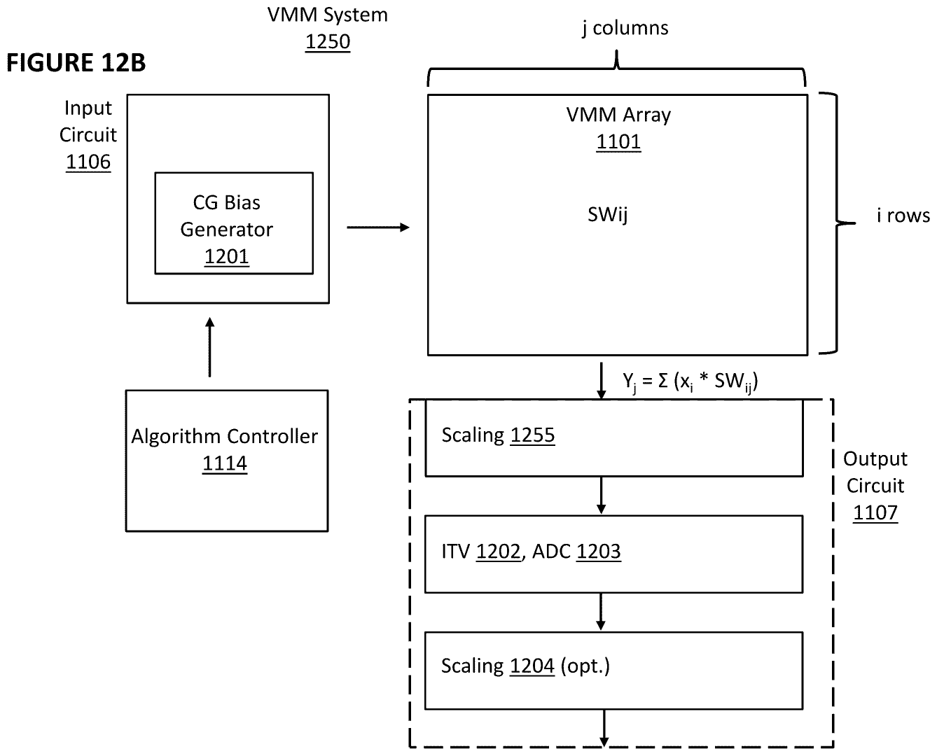

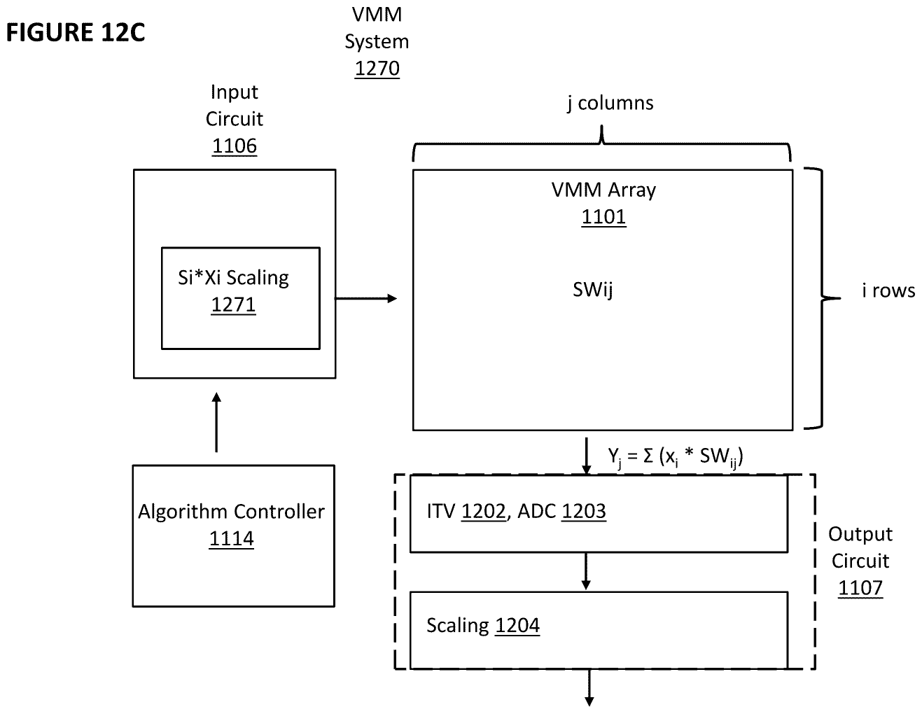

FIG. 12A depicts VMM system 1200, which is an example instantiation of VMM system 1100 of FIG. 11. VMM system 1200 comprises VMM array 1101, algorithm controller 1114, input circuit 1106, and output circuit 1107 as in VMM system 1100. Input circuit 1106 comprises control gate bias generator 1201. Output circuit 1107 comprises current-to-voltage converter 1202, analog-to-digital converter 1203, and scaling block 1204.

During a programming operating, the weights to be stored in VMM array 1101, Wij, are scaled (either up-scaled or down-scaled) to become scaled weights SWij. In one example, the weight value is scaled by a factor of S (scale), and the scaled weight is programmed into the memory cells. For example, for a cell storing weight=3 nA, with S (scale)=4, the new weight value is 3*4=12 nA, meaning that the cell is programmed such that when its value is read, the read output will be 12 nA instead of 3 nA. For this scale factor of 4, a weight of 6 nA will be scaled to 24 nA and the cell will be programmed to output 24 nA when it is read.

In another example, N cells are used to store a weight (aka copied cells/weights or replica cells/weights), e.g., N=2 to 8, with all cells storing an identical weight value. For example, if a weight value is 9 nA, with N=4, the weight value is now 9*4=36 nA which is implemented by storing 9 nA in four cells. In another example, the N cells may each have different weight values.

In another example, the full range of possible weight values to be stored in the array is scaled. For example, if 96 nA represents the full range for a 5-bit cell (that is, a cell that can store 32 different levels, with the difference between levels equal to 3 nA, the range can be scaled by a factor of two so that 192 nA becomes the full range for the possible values (that, a cell can store 32 different levels, with the difference between levels equal to 6 nA).

In another example, the scaling is achieved by control gate bias generator 1201 applying a bias voltage to the control gate line of the row being programmed. The same or a different bias voltage is applied during verify and read operations. Control gate bias generator 1201 determines the bias voltage based in part of data from algorithm controller 1114, which will provide a scaling parameter to control gate bias generator 1201 based on knowledge of the type of neural network being implemented and the level within the neural network.

For example, if the range of possible activation inputs is 0 to 255 for an 8-bit activation input, the control gate bias range might be between 0.5V (for an activation input of 0) and 1.5V (for an activation input of 255). In one example, for an activation input 255 (which is the largest input for an 8-bit input), the control gate bias is 1.5V during both verify and read operations, meaning that the cell current drawn will be the same for verify and read operations. In another example, for an activation input 255, the control gate bias is 1.3V for verify operations but >1.0V (such as 1.5V) for read operations, meaning that the cell current drawn will be different for verify and read operations. In this example the cell current during a verify operation might be 96 nA for an activation input of 255 but much greater than 96 nA (such as around 360 nA) during a read operation for the same activation input.

The control gate bias range can be configured based on the type of neural network being implemented (for example, an MLP, CNN, RNN, or other type of network), the nature of the layer being implemented (for example, the first layer, a middle layer, or the last layer), on neural CNN operation being performed (for example, depthwise, 1D, or 2D), on the filter size or kernel size (for example, 3×3, 1×1, 7×7, or other size), on the channel depth (for example, 32, 64, 128, or another size).

Output scaling block 1204 optionally can be used to scale back the digital output from ADC 1203 by an output scale factor to the values that would have been generated without the application of a control gate bias voltage by control gate bias generator 1201. Alternatively, the output scale factor can scale the output to other values.

FIG. 12B shows VMM system 1250 with scaled weight similar to that in FIG. 12A with a neuron output (e.g., array output current) scaling block 1255 to scale (either up-scale or down-scale) the array output before going into the ITV and ADC blocks. The output scaling block 1204 scales the digital output from ADC 1203 and is optional.

FIG. 12C shows VMM system 1270 comprising input circuit 1106 that generates scaled input 1271 and other blocks performing the same functions as in FIG. 12A. Input circuit 1106 scales the input by a factor Si and the applies the scaled input to VMM array 1101.

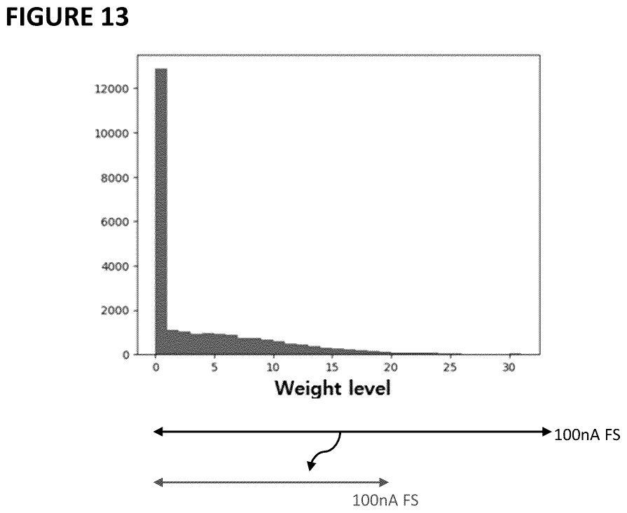

FIGS. 13 to 16 depict the determining the scaling factor by the distribution data.

FIG. 13 depicts a weight distribution for Layer 8 of a Mobilnet neural network. As can be seen, the weight is largely distributed at maximum value=20 or less. For this example, the weight has 5-bit resolution, meaning the weight has 32 levels, which is shown in the horizontal axis. The entire range which goes up to value=32 utilizes a current range of 100 nA even though the upper weights are rarely used. An example of a scaling to apply is a factor of 32/20. All the weights in this layer would multiplied by this factor. Other scaling factor can be considered such as by the value at 1-sigma or any from 1- to 3-sigma or by a percentage such as the value at which as 80-95% of weights are contained. The scale factor is then equal to the weight full scale (FS, e.g. 32) divided by this number.

In another example, the scaling factor is determined such that the neural network performance is degraded by a target factor, such as 0.25% accuracy.

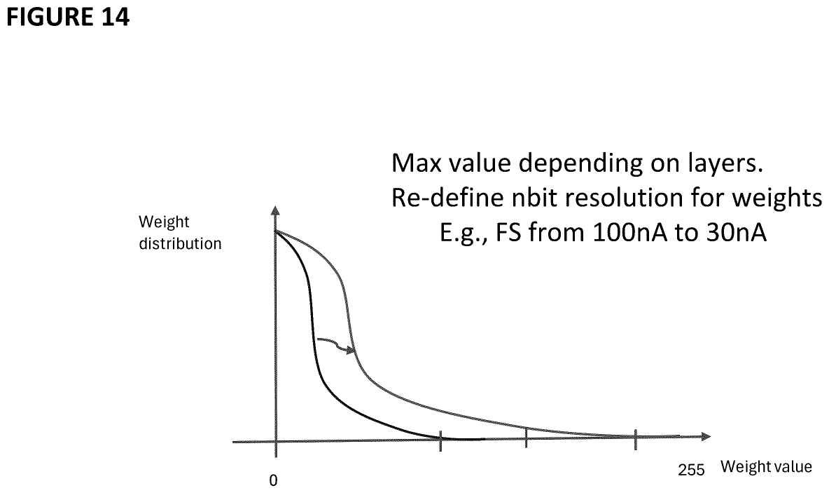

FIG. 14 depicts another weight distribution where the weights can range from 0 to 255, where the weights are represented by 8-bit values. As can be seen, the weights do not use the entire range of possible weights, so a scaling technique can multiple each weight by a scaling factor greater than 1 as determined as above for FIG. 13, such that more of the entire range is utilized.

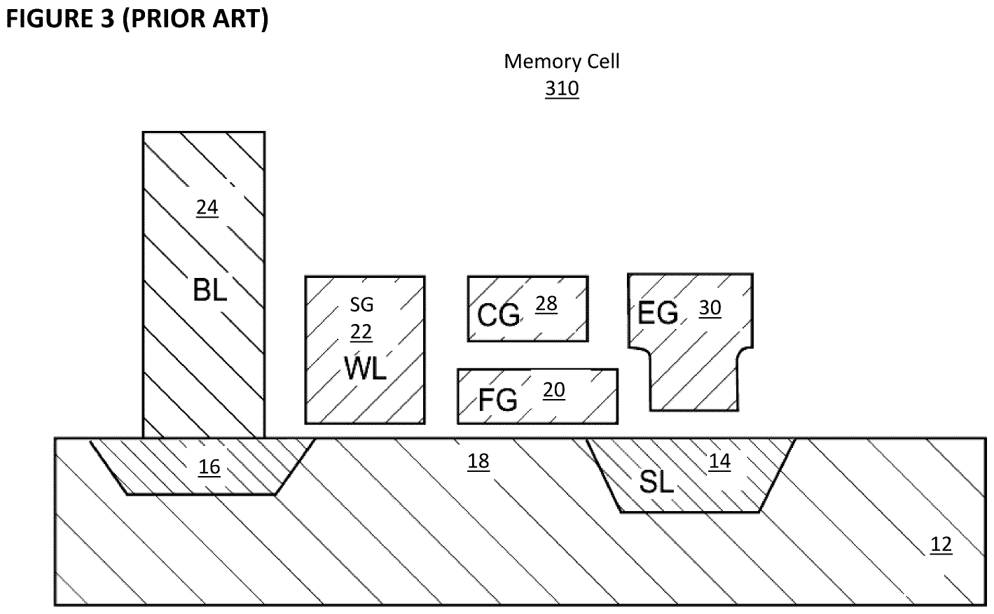

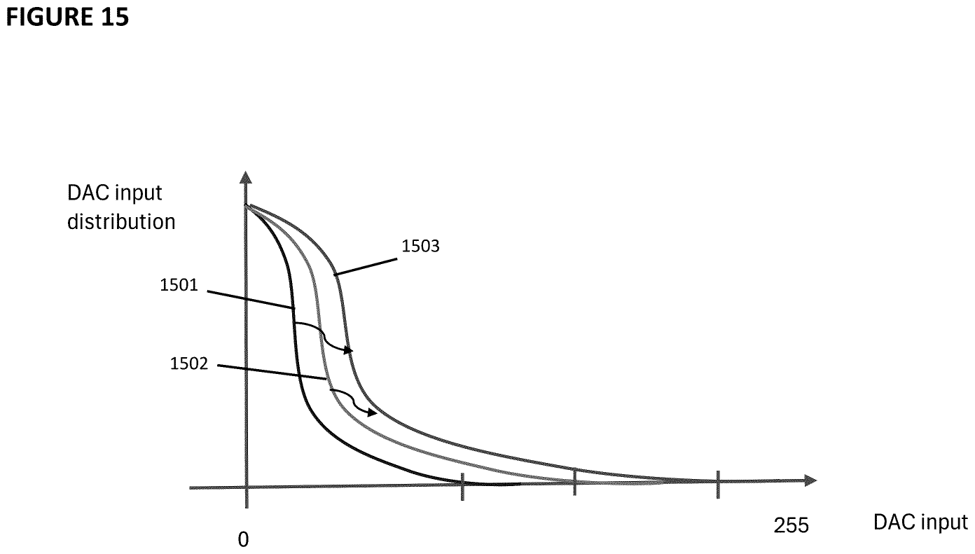

FIG. 15 depicts another input (activation) distribution where the input can range from 0 to 255, where the inputs are 8-bit values. Input distribution 1501 in this example is the distribution of inputs for a first layer, and input distribution 1502 is distribution of inputs for a second layer. The weights of both layers can be scaled using a scaling technique that multiplies each weight by a scaling factor similarly determined as in FIG. 3, such that more of the entire range is utilized.

The scaling factor can be applied mathematically to the weight values before they are stored, or a bias voltage can be applied to the array at the time the weight is programmed, which will effectively cause a modified weight to be stored instead. The bias voltage can be chosen to effectively cause input distribution 1503 to be used instead of input distributions 1501 and 1502.

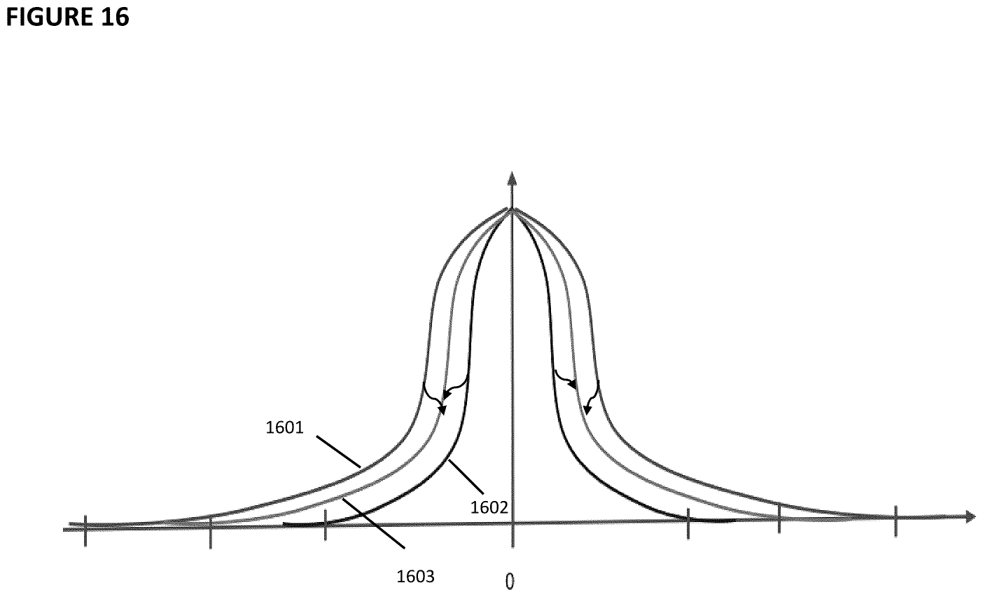

FIG. 16 depicts distributions of neuron output. Distribution 1601 is a distribution for neuron output from a first layer, and distribution 1602 is a distribution for neuron output from a second layer. The weights of both layers can be scaled to distribution 1603 using a scaling technique that multiplies each weight by a scaling factor greater than 1 or less than 1 similarly as described in FIG. 13, such that more of the entire range is suitable for the output circuit.

The scaling factor can be applied mathematically to the weight values before they are stored, or a bias voltage can be applied to the array at the time the weight is programmed, which will effectively cause a modified weight to be stored instead. The bias voltage can be chosen to effectively cause distribution 1603 to be used instead of distributions 1601 and 1602.

Scaling up the weight can be applied for convolution operations with less channel depth as might be the case in the first layer of a neural network, for depth-wise convolution, for point-wise convolution, or when a small kernel size is used (such as a 1×1 kernel).

As used herein, the terms “over” and “on” both inclusively include “directly on” (no intermediate materials, elements or space disposed therebetween) and “indirectly on” (intermediate materials, elements or space disposed therebetween). Likewise, the term “adjacent” includes “directly adjacent” (no intermediate materials, elements or space disposed therebetween) and “indirectly adjacent” (intermediate materials, elements or space disposed there between), “mounted to” includes “directly mounted to” (no intermediate materials, elements or space disposed there between) and “indirectly mounted to” (intermediate materials, elements or spaced disposed there between), and “electrically coupled” includes “directly electrically coupled to” (no intermediate materials or elements there between that electrically connect the elements together) and “indirectly electrically coupled to” (intermediate materials or elements there between that electrically connect the elements together). For example, forming an element “over a substrate” can include forming the element directly on the substrate with no intermediate materials/elements therebetween, as well as forming the element indirectly on the substrate with one or more intermediate materials/elements there between.

What is claimed is:

1. A system comprising:
an array of non-volatile memory cells arranged in rows and columns;
a control gate bias generator to generate a bias voltage to apply to a control gate line coupled to a row of non-volatile memory cells in the array; and
an algorithm controller to configure the control gate bias generator based on a layer of a neural network to be stored in the array.

2. The system of claim 1, wherein the bias voltage is applied to scale weights stored in one or more of the non-volatile memory cells in the array.

3. A method comprising:
receiving a first set of weight values; and
programming a second set of weight values into non-volatile memory cells, where the second set of weight values are equal to the first set of weight values scaled by a scaling factor S, and the scaling is achieved by storing each weight value in the first set of weight values in S non-volatile memory cells.

4. The method of claim 3, comprising:
receiving an output from the non-volatile memory cells; and
and scaling down the output to generate a down-scaled output.

5. The method of claim 4, comprising:
converting the down-scaled output into a voltage.

6. The method of claim 5, comprising:
converting the voltage into a set of digital bits.

7. The method of claim 3, comprising:
performing the receiving and programming for a plurality of different layers in a neural network with a different scaling factor applied to each layer.

8. The method of claim 3, comprising:
performing the receiving and programming for a plurality of different neural networks with a different scaling factor applied to each neural network.

9. The method of claim 3, wherein the non-volatile memory cells are contained in a neural network memory.

10. The method of claim 3, wherein the non-volatile memory cells are contained in an analog memory.

11. The method of claim 4, wherein the scaling down is performed on an output of an analog-to-digital converter.

12. A method comprising:
receiving a first set of weight values; and
programming a second set of weight values into non-volatile memory cells, where the second set of weight values are equal to the first set of weight values scaled by a scaling factor S, where S is based on a distribution of input values and the full scale range of the input values.

13. The method of claim 12, wherein the scaling factor S is determined by value at between 1-sigma to 3-sigma of the distribution of input values and the full scale range of the input values.

14. The method of claim 12, comprising:
receiving an output from the non-volatile memory cells; and
scaling down the output to generate a down-scaled output.

15. The method of claim 14, comprising:
converting the down-scaled output into a voltage.

16. The method of claim 15, comprising:
converting the voltage into a set of digital bits.

17. The method of claim 12, comprising:
performing the receiving and programming for a plurality of different layers in a neural network with a different scaling factor applied to each layer.

18. The method of claim 12, comprising:
performing the receiving and programming for a plurality of different neural networks with a different scaling factor applied to each neural network.

19. The method of claim 12, wherein the non-volatile memory cells are contained in a neural network memory.

20. The method of claim 12, wherein the non-volatile memory cells are contained in an analog memory.

21. The method of claim 14, wherein the scaling down is performed on an output of an analog-to-digital converter.

22. A method comprising:
receiving a first set of weight values; and
programming a second set of weight values into non-volatile memory cells, where the second set of weight values are equal to the first set of weight values scaled by a scaling factor S, where S is based on a distribution of weights in the first set of weight values and the full scale range of the weight values in the first set of weight values.

23. The method of claim 22, wherein the scaling factor S is determined by value at between 1-sigma to 3-sigma of the distribution of weights in the first set of weight values and the full scale range of the weight values.

24. The method of claim 22, comprising:
receiving an output from the non-volatile memory cells; and
and scaling down the output to generate a down-scaled output.

25. The method of claim 24, comprising:
converting the down-scaled output into a voltage.

26. The method of claim 25, comprising:
converting the voltage into a set of digital bits.

27. The method of claim 22, comprising:
performing the receiving and programming for a plurality of different layers in a neural network with a different scaling factor applied to each layer.

28. The method of claim 22, comprising:
performing the receiving and programming for a plurality of different neural networks with a different scaling factor applied to each neural network.

29. The method of claim 22, wherein the non-volatile memory cells are contained in a neural network memory.

30. The method of claim 22, wherein the non-volatile memory cells are contained in an analog memory.

31. The method of claim 24, wherein the scaling down is performed on an output of an analog-to-digital converter.

32. A method comprising:
receiving a first set of weight values; and
programming a second set of weight values into non-volatile memory cells, where the second set of weight values are equal to the first set of weight values scaled by a scaling factor S, where S is based on: (i) a distribution of input values and the full scale range of the input values; (ii) a distribution of weights in the first set of weight values and the full scale range of the weight values; and (iii) a distribution of neuron distribution values and the full scale range of neuron distribution values.

33. A method comprising:
reading a plurality of non-volatile memory cells in an array of non-volatile memory cells to produce a single weight value in a layer of a neural network.

34. The method of claim 33, wherein the plurality of non-volatile memory cells each store the same value.

35. The method of claim 33, wherein the plurality of non-volatile memory cells each store different values.

36. The method of claim 33, wherein the plurality of non-volatile memory cells each draw the same current during a read operation.

37. The method of claim 33, wherein the plurality of non-volatile memory cells each draw a different current during a read operation.

38. A method comprising:
reading memory cells storing a scaled weight value.

39. The method of claim 38, wherein the scaling is by a scaling factor S, where S is based on: (i) a distribution of input values and the full scale range of the input values; (ii) a distribution of weights in a first set of weight values and the full scale range of the weight values; and (iii) a distribution of neuron distribution values and the full scale range of neuron distribution values.

40. A method comprising:
an array of non-volatile memory cells arranged in rows and columns;
programming weights into selected non-volatile memory cells in array of non-volatile memory cells using a first control gate bias voltage applied to control gate terminals of the selected non-volatile memory cells;
reading the selected memory non-volatile memory cells using a second control gate bias voltage applied to the control gate terminals of the selected non-volatile memory cells, wherein the second control gate bias voltage is different than the first control gate bias voltage.
